(19) United States
(12) Patent Application Publication
(10) Pub. No.: US 2025/0204058 A1
(43) Pub. Date: Jun. 19, 2025

(54) Avalanche Photodiode With Field Plates

(71) Applicant: TEXAS INSTRUMENTS INCORPORATED, Dallas, TX (US)

(72) Inventors: Henry L. Edwards, Garland, TX (US); Gerd Schuppener, Allen, TX (US); Ruchika Dhawan, McKinney, TX (US); Wenjuan Fan, Allen, TX (US)

(21) Appl. No.: 18/540,992

(22) Filed: Dec. 15, 2023

(51) Int. Cl. H01L 31/107; H01L 29/40; H01L 31/02

(52) U.S. Cl. CPC H10F 30/2255; H10D 64/112; H10F 77/959

(57) ABSTRACT

A semiconductor device including a semiconductor substrate having a surface, an N-type doped region in the semiconductor substrate, and a P-type doped region in the semiconductor substrate. The P-type and N-type doped regions form a first PN junction that orients along a first axis parallel to the surface. The semiconductor substrate includes a second PN junction that orients along a second axis that intersects the surface. The second PN junction includes one of the N-type or P-type doped regions. A first field plate is electrically coupled to the N-type doped region and extends over a first part of the semiconductor substrate between the N-type and P-type doped regions. A second field plate is electrically coupled to the P-type doped region and extends over a second part of the semiconductor substrate between the N-type and P-type doped region. The first and second field plates are separated by a gap.

### BACKGROUND

An optical sensor may include photodiodes to converts light to an electrical signal (e.g., photocurrent) representing a measurement of the light intensity. One example of photodiode is avalanche photodiode, which makes use of carrier multiplication through impact ionization to achieve photocurrent multiplication to improve sensitivity. An avalanche photodiode has an anode and a cathode, and a voltage is applied across the anode and cathode such that a PN junction within the avalanche photodiode is reverse biased. Impact ionization may occur when the electric field across the reversed biased PN junction exceeds a threshold.

### SUMMARY

In one example, a semiconductor device including a semiconductor substrate, an N-type doped region in the semiconductor substrate, and a P-type doped region in the semiconductor substrate. The P-type doped region is lateral with respect to the N-type doped region. A vertical PN junction is in the semiconductor substrate. The vertical junction includes one of the N-type or P-type doped regions. A first terminal is electrically coupled to the N-type doped region, and a second terminal is electrically coupled to the P-type doped region. A first field plate is electrically coupled to the N-type doped region and extends over a first part of the semiconductor substrate between the N-type and P-type doped regions. A second field plate is electrically coupled to the P-type doped region and extends over a second part of the semiconductor substrate between the N-type and P-type doped region. The first and second field plates are separated by a gap.

In another example, a circuit includes an avalanche photodiode having a cathode, an anode, a first field plate coupled to the cathode, and a second field plate coupled to the anode. A bias circuit is coupled to the first and second terminals.

In yet another example, an avalanche photodiode includes a semiconductor substrate, an N-type doped region in the semiconductor substrate, and a P-type doped region in the semiconductor substrate. The P-type doped region is lateral with respect to the N-type doped region. A vertical PN junction is in the semiconductor substrate and includes one of the N-type or P-type doped regions. A first terminal is electrically coupled to the N-type doped region. A second terminal is electrically coupled to the P-type doped region. A first conductive plate is electrically coupled to the N-type doped region and extends over a first part of the semiconductor substrate between the N-type and P-type doped regions. A second conductive plate is electrically coupled to the P-type doped region and extends over a second part of the semiconductor substrate between the N-type and P-type doped region. The first and second field plates being separated by a gap. A dielectric layer is over the N-type doped region and the P-type doped region. The first and second conductive plates are in the dielectric layer.

### BRIEF DESCRIPTION OF THE DRAWINGS

FIG. 1 is a schematic diagram of an avalanche photodiode, in an example.

FIGS. 2A and 2B are schematic diagrams of the avalanche photodiode of FIG. 1 illustrating the direction of electric fields, in an example.

FIG. 3 is a schematic diagram of an avalanche photodiode having field plates, in an example.

FIGS. 4A and 4B are schematic diagrams of the avalanche photodiode of FIG. 3 illustrating that the electric fields associated with the avalanche photodiode of FIGS. 1-2B are reduced due to the field plates, in an example.

FIG. 5 is a schematic diagram of the avalanche photodiode of FIG. 3 illustrating that movement of charge, in an example.

FIG. 6 is a schematic diagram of an avalanche photodiode having field plates and an optically-opaque layer over a portion of a dielectric layer containing the field plates, in an example.

FIG. 7 is a schematic diagram of an avalanche photodiode having field plates, in another example.

FIG. 8A is a top-down view of an avalanche photodiode having field plates in a ringed configuration, in an example.

FIG. 8B is a cross-sectional view of the ringed configuration of FIG. 8A, in an example.

FIG. 9 is a circuit in which an avalanche photodiode having field plates can be used.

### DETAILED DESCRIPTION

The same reference numbers or other reference designators are used in the drawings to designate the same or similar (either by function and/or structure) features.

As described above, an avalanche photodiode makes use of carrier multiplication through impact ionization to achieve photocurrent multiplication. An avalanche photodiode has an anode (formed with a P-type region) and a cathode (formed with an N-type region), and an absorption region and a multiplication region between the anode and the cathode. When the avalanche photodiode operates under a reverse bias voltage between the anode and the cathode (e.g., where the cathode is biased at a more positive voltage than the anode), photons entering the photodiode can be absorbed in the absorption region, and electron-hole pairs can be created. The reverse bias voltage creates an electric field between the anode and the cathode, and the electric field can sweep the electrons to the cathode and the holes to the anode by the electric field. In a case where the reverse bias voltage close to the breakdown voltage of the photodiode, which creates a high electric field between the cathode and the anode, impact ionization can occur, where the charge carriers (electrons/holes) created in the absorption region have high energy due to the high electric field, and the high energy charge carriers can enter the multiplication region and create additional electron-hole pairs there by impact. Through carrier multiplication, the sensitivity of the avalanche photodiode (and the optical sensor) in detecting and measuring photons can be improved.

Some avalanche photodiodes have the anode and cathode on opposite sides of the semiconductor substrate. In planar integrated circuit (IC) technologies, however, the terminals of the IC are on the same side of the semiconductor substrate. Accordingly, for a planar-based avalanche photodiode, the anode and cathode are on the same side (e.g., front side) of the semiconductor substrate, and electrodes connected to the anode and the cathode are in a dielectric layer (e.g., silicon oxide) on the semiconductor substrate. The semiconductor substrate can have a highly doped P region (P++ region) and a highly doped N region (N++ region) laterally arranged on a top surface (e.g., front side surface) of the semiconductor substrate. The P++ region is configured as part of the anode, and the N++ region is configured as part of the cathode. The N++ region is in a deep N-well. The P++ region and the N++ region may form a lateral PN junction that orients along an axis parallel to the top surface of the semiconductor substrate.

The semiconductor substrate may also include a lightly-doped epitaxial layer (epi) configured as the absorption region, and a doped region having a lower dopant concentration than the anode/cathode but a higher dopant concentration than the epi configured as the multiplication region. The semiconductor substrate may also include an N+buried layer electrically coupled to the deep N-well as part of the cathode. In some examples, the semiconductor substrate, the multiplication region, and the absorption region can each be P-type. In some examples, the avalanche photodiode may include a PN junction comprising the N++ region on the substrate surface, and the P-type substrate, with the P-type multiplication region and the P-type absorption region between the N++ region and the P-type substrate. The PN junction is oriented along an axis that intersects the substrate's top surface. In some examples, the avalanche photodiode may be in the form a PN junction comprising the P++ region on the substrate surface and the N+ buried layer, with the P-type multiplication region and the P-type absorption region between the P++ region and the N+ buried layer, and the PN junction is oriented along an axis that intersects the substrate's top surface. In some examples, the N-well and the N+ buried layer can be part of a junction isolation structure of a bipolar—CMOS (complementary metal oxide semiconductor)—DMOS (double diffusion metal oxide semiconductor) (BCD) process providing isolation to the P++ region, but with an N++ region added in the deep N-well to provide electrical connection to the cathode, and the vertical PN junction is reverse-biased at a voltage higher than a breakdown voltage to facilitate impact ionization (and avalanche breakdown), which is not a typical operation for a junction isolation structure.

As described above, to facilitate impact ionization in the multiplication region, a large voltage can be applied across the anode and the cathode to reverse bias the vertical PN junction. The reverse bias voltage can be close to the breakdown voltage of the photodiode to create impact ionization in the multiplication layer. However, the lateral PN junction (between the P++ and N++ region on the substrate surface) should not operate close to breakdown under this reverse bias voltage, otherwise avalanche multiplication may also occur at the lateral PN junction, and a large reverse current may flow and contaminate the photocurrent. However, the strong reverse bias voltage may create a strong lateral surface electric field between the P++ and N++ regions, which can lead to breakdown and avalanche multiplication in the lateral PN junction. One way to reduce the lateral electric field (for a given reverse bias) is to increase the lateral distance between the P++ and N++ regions. Such arrangements, however, increases the non-photo-active surface area of the avalanche photodiode. Accordingly, fewer avalanche photodiodes can be packed within a given optical sensor area, which can reduce the resolution of the optical sensor.

In addition, as described above, a large reverse bias voltage can be applied between the anode and cathode to create a large vertical electric field across the vertical PN junction to facilitate impact ionization. But the large reverse bias voltage can also create a large vertical surface electric field near the substrate surface. This is due to the mismatch in the dielectric constants between the dielectric layer and the semiconductor substrate, which creates peak electric field at the interface between the dielectric layer and the semiconductor substrate. This peak surface electric field may cause ionization at the semiconductor substrate. The peak surface electric field also create hot carrier effect, where charge carriers created by the ionization also have high enough energy due to the large peak surface electric field and penetrate into the dielectric layer. Those charge carriers can chemically react with the dielectric layer to create additional charge carriers, which can accumulate in the dielectric layer near the substrate surface and above a substrate region between the P++ and N++ regions. The accumulated charge carriers in the dielectric layer can create a conduction channel in the substrate region between the P++ and N++ regions, which may severely limit the avalanche photodiode's lifetime. The chemical reaction can also degrade the dielectric layer and severely limit the dielectric layer's lifetime.

The examples described herein pertain to a planar-based avalanche photodiode that has a field plate coupled to the anode and another field plate coupled to the cathode. The field plates can receive the same bias voltages through the respective anode and cathode. The electric field produced by the field plates can reduce the vertical (or non-lateral) surface electric field otherwise produced near the interface between the semiconductor substrate and the dielectric layer, and/or move the high equipotential lines (lines representing high voltages/potentials) of the electric field from the interface to within the vertical PN junction, which can reduce the hot carrier effect and accumulation of charge carriers at the interface between the dielectric layer and the semiconductor substrate. Because of the reduced charge carriers at the interface, the avalanche photodiode described herein advantageously is less susceptible to the creation of the conducting channel as described above. Accordingly, the avalanche diode described herein may have a longer usable life than a planar-based avalanche photodiode without field plates.

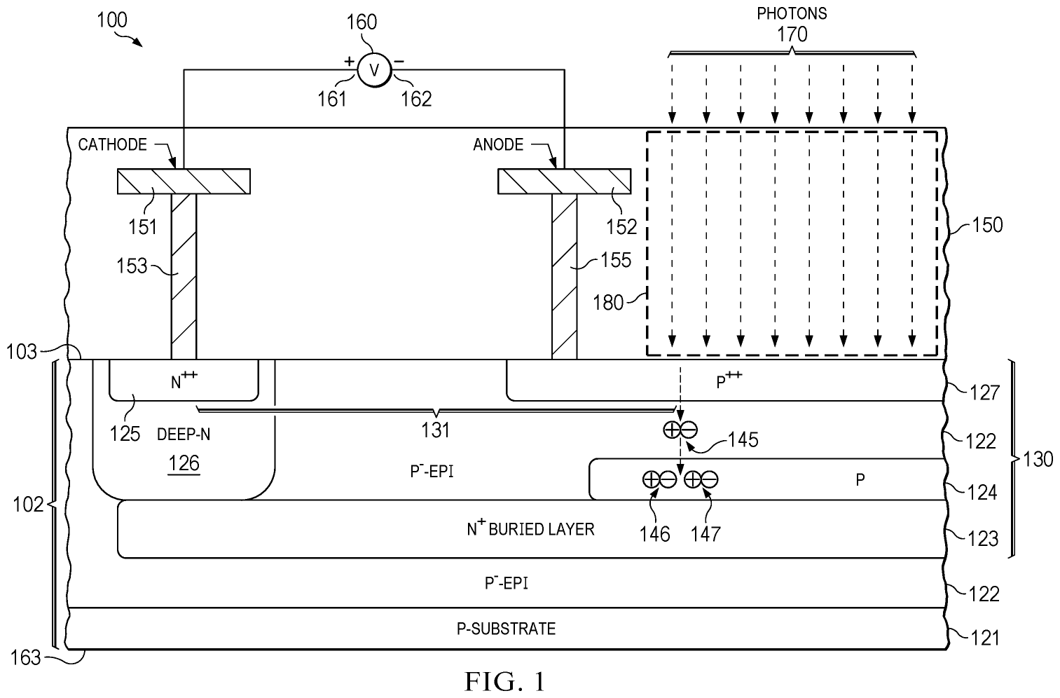

FIG. 1 is a cross-sectional view of an avalanche photodiode 100, in an example. Avalanche photodiode 100 includes a semiconductor substrate 102 having a surface 103, and a dielectric layer 150 on surface 103. The dielectric layer 150 can include, for example, silicon dioxide. In the semiconductor substrate 102 (and surface 103), various semiconductor processing operations can be performed to form active devices including the various regions shown in FIG. 1. For example, P-type dopants can be added to undoped silicon to form a P-type substrate 121. A P-type doped epitaxially formed layer 122 (P-type epi layer) can be formed on the P-type substrate 121. An N-type doped buried layer 123 is then formed within a portion of the P-type epi layer 122 through the inclusion of N-type dopants. Within the P-type epi layer 122, a N-type doped region 126 (e.g., a deep N-well) is formed. Within the N-type region 126, an N-type doped region 125 is formed. The N-type doped region 125 may be an N++ region and is more highly doped than the N-type doped region 126. A P-type doped region 124 is formed within the P-type epi layer 122. A P-type doped region 127 is also formed within the P-type epi layer 122 and is lateral (e.g., along an axis parallel with surface 103) with respect to the N-type doped region 125. The P-type doped region 127 can be a P++ region and is more heavily doped than the P-type doped region 124 and/or the P-type epi layer 122. The combination of the P-type doped region 127, P-type epi layer 122, P-type doped region 124, and the N-type doped buried layer 123 forms a vertical stack (e.g., along an axis that intersects surface 103) and can form a PN junction 130 within the avalanche photodiode 100. PN junction 130 is oriented along an axis that intersects surface 130, where the P-type doped region 124 can be configured as a multiplication region, and the P-type epi layer 122 can be configured as an absorption region. In some examples, semiconductor substrate 102 can be part of a BCD process, where N-type doped region 126 (deep N-well) and N-type doped buried layer 123 are part of a junction isolation structure providing isolation to P-type doped region 127, but with N-type doped region 125 (N++ region) added to form part of the cathode. But PN junction 130 is reverse-biased at a voltage close to a breakdown voltage to facilitate impact ionization (and avalanche breakdown), as to be described below.

Avalanche photodiode 100 also includes a PN junction 131 formed by P-type region 127, P-type epi layer 122, and N-type doped region 125. PN junction 131 is oriented along an axis parallel to surface 103. For avalanche photodiode 100 to function correctly, the breakdown voltage of PN junction 131 should be larger than the breakdown voltage of PN junction 130.

The dielectric layer 150 includes a cathode terminal 151 (or simply cathode 151) and an anode terminal 152 (or simply anode 152) on surface 103. The cathode 151 is electrically coupled to the N-type doped region 125 by way of a conductor 153 (e.g., a metal via). Similarly, the anode 152 is electrically coupled to the P-type doped region 127 by way of a conductor 155 (e.g., a metal via). The cathode 151, anode 152, and conductors 153 and 155 may be formed after the formation of the dielectric layer 150. Alternatively, the cathode 151, anode 152, and conductors 153 and 155 may be formed before formation of the dielectric layer 150, and the encapsulated with dielectric material to form the dielectric layer 150. In this example, the anode 152 is over PN junction 130. In some examples (not shown in the figures), cathode 151 and anode 152 and conductors 153 and 155 can be on a surface 163 of P-type substrate 121 opposing surface 103. In such examples, surface 103 can be a front-side surface and surface 163 can be a back-side surface, and cathode 151 and anode 152 and conductors 153 and 155 can be part of a metallized back-side of P-type substrate 163.

The cathode 151 and anode 152 are reverse biased by way of a voltage from a bias voltage circuit 160. Bias voltage circuit 160 includes terminals 161 and 162. The voltage on terminal 161 is positive relative to the voltage on terminal 162. Terminal 161 is coupled to the cathode 151, and terminal 162 is coupled to the anode 152. Accordingly, the cathode 151 and N-type doped region 125 are at a positive potential with respect to the anode 152 and P-type doped region 127. The magnitude of the bias voltage 160 can be fairly high but below the avalanche breakdown voltage of avalanche photodiode 100. The magnitude of the electric field generated by reverse biasing the avalanche photodiode 100 is fairly large in the P-type doped region 124.

At least a portion 180 of the dielectric layer 150 is transparent to photons 170 of light. Photons 170 pass through the dielectric layer 150. Upon reaching the semiconductor substrate 102, a photon 170 can be absorbed in the P-type epi layer 122 and an electron-hole pair 145 is formed. One electron-hole pair 145 is formed for each absorbed photon 170 of light. The electric field generated by reverse biasing the avalanche photodiode 100 causes each electron-hole pair to separate into its constituent hole and electron. The electrons flow into the P-type doped region 124 where the magnitude of the electric field is relatively large. Due to the relatively large electric field in the P-type doped region 124, each carrier entering the P-type doped region 124 can create multiple secondary electron-hole pairs (e.g., electron-hole pairs 146 and 147) through impact ionization. Each one of the initial secondary electron-hole pairs can, in turn, generate additional electron-hole pairs, and so on. Accordingly, the P-type doped region 124 performs a multiplication function by which each photon 170 results in multiple electron-holes pairs thereby boosting the magnitude of the current from the avalanche photodiode 100 due to the photons 170. The electrons created in the P-type doped region 124 flow upward into the P-type doped region 127 and to the anode 152.

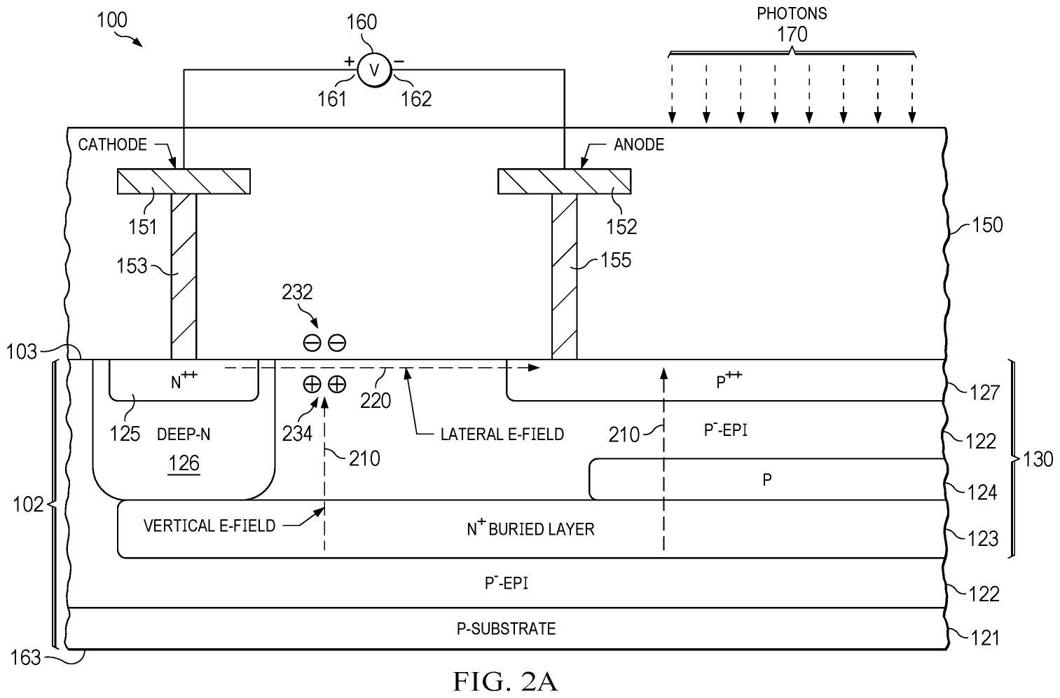

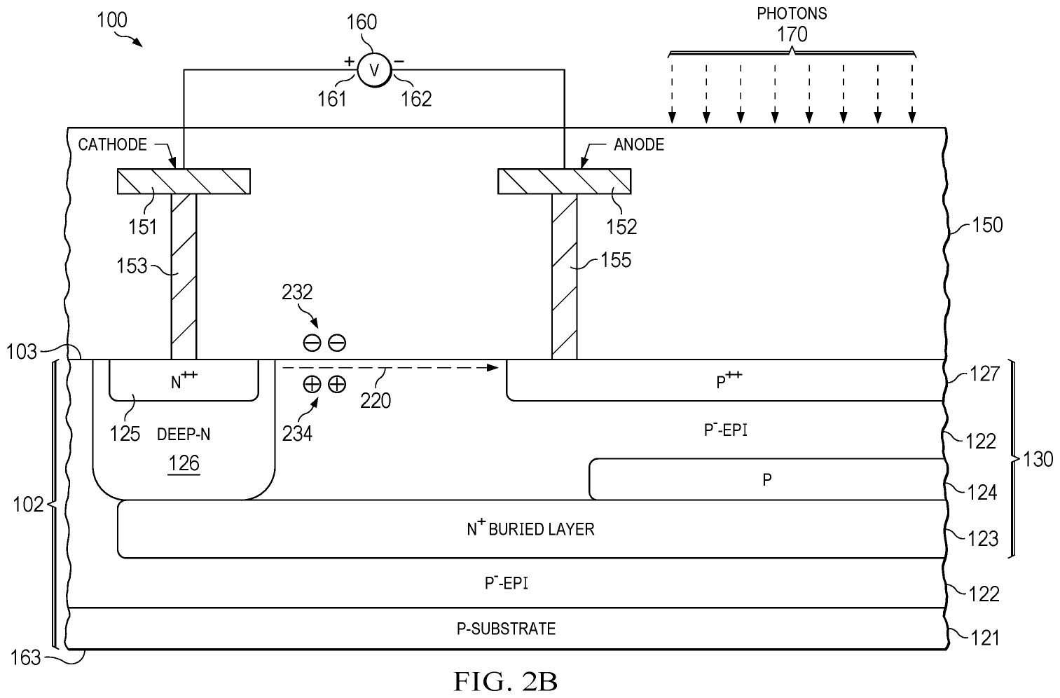

FIGS. 2A and 2B are the same cross-sectional view of avalanche photodiode 100 as in FIG. 1. The positive voltage of bias voltage circuit 160 is provided to the cathode 151, the N-type doped region 125, the N-type doped region 126, and the N-type doped buried layer 123. The negative voltage of the bias voltage circuit 160 is provided to the anode 152, the P-type doped region 127 and the P-type epi layer 122. The potential difference between the N-type doped buried layer 123 and the P-type doped region 127 creates a vertical electric field 210 that intersects surface 103. The potential difference between the N-type doped region 125 and P-type doped region 127 creates a lateral electric field 220 at or near surface 103. As explained above, a large lateral electric field 220 may cause the lateral PN junction between N-type doped region 125 and P-type doped region 127 to operate in the breakdown regime, where avalanche multiplication occurs and a large reverse current can flow from the N-type doped region 125 to the P-type doped region 127 and contaminate the charge carriers generated by the multiplication region (P-type doped region 124) representing the photocurrent, leading to failure in the avalanche photodiode operation. The life time of the avalanche photodiode may also be reduced as a result.

Also, due to the mismatch in the dielectric constants between dielectric layer 150 and semiconductor substrate 102, vertical electric field 210 peaks at surface 103. This peak surface electric field causes free electrons (electrons not tied to an atom) to move in the direction of the vertical electric field 210. Electrons entering the P-type doped region 127 can move along conductor 155 to cathode 152. However, in the area between the N-type doped region 125 and the P-type doped region 127, the vertical electric field 210, which is large enough to cause impact ionization in the P-type doped region 124, can create hot carrier effect, where the vertical electric field 210 causes ionization in the P-type epi layer 122 and create charge carriers (e.g., holes) 234, the charge carriers are provided with sufficient energy by the peak vertical electric field 210 to penetrate into the dielectric layer 150 via surface 103. The charge carriers 234 can with the dielectric layer 150 to create electrons 232 in the dielectric layer 150 at the interface. The electrons 232 in the dielectric layer 150 can attract charge towards surface 103 and create a lateral conduction channel between the P-type doped region 127 and the N-doped region 125 below (and parallel with) surface 103, which can reduce the breakdown voltage of the PN junction 131 between the P-type doped region 127 and the N-doped region 125. This makes it even easier for the avalanche breakdown to occur in the PN junction 131, leading to failure and life time reduction of the avalanche photodiode. The reaction between the electrons 232 and the dielectric layer 150 can also degrade and reduce the life time of the dielectric layer 150.

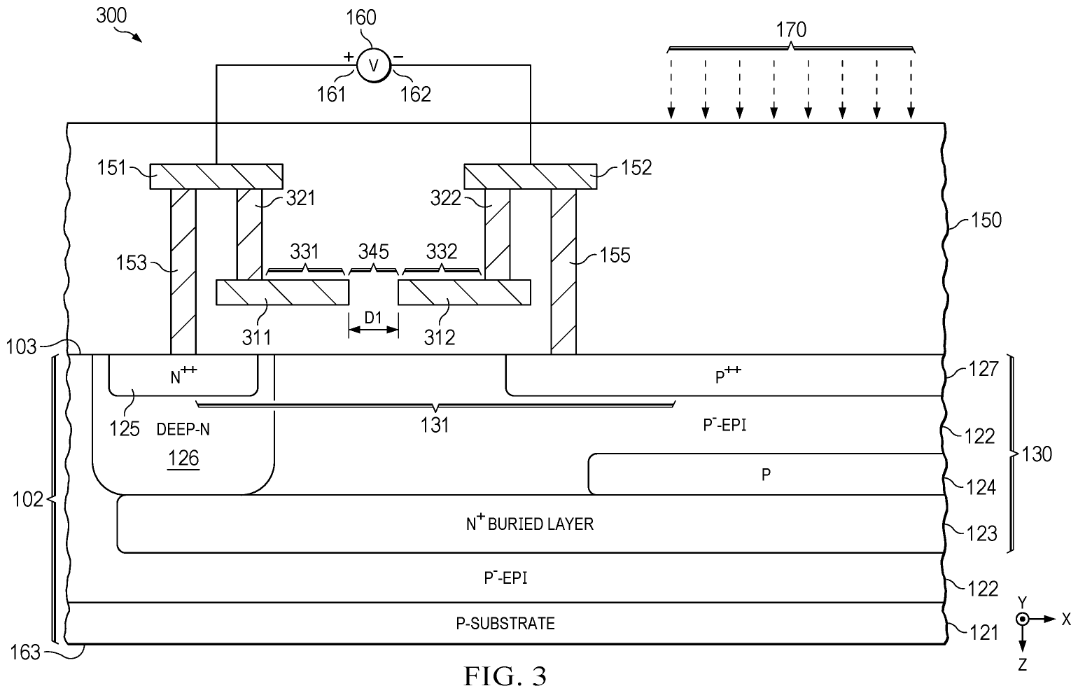

FIG. 3 is a cross-sectional view of an avalanche photodiode 300 that can mitigate at least some of the issues described above. Avalanche photodiode 300 also includes the dielectric layer 150 on the semiconductor substrate 102 as described above. The semiconductor substrate 102 includes the same regions and layers as in the example avalanche photodiode 100 of FIGS. 1-2B. For example, the avalanche photodiode 300 of FIG. 3 includes the N-type doped region 125 in the semiconductor substrate 102 and the P-type doped region 127 in the semiconductor substrate 102. The P-type doped region 127 is lateral with respect to the N-type doped region 125. The avalanche photodiode 300 also includes the vertical PN junction 130, described above. The cathode 151 and anode 152 are electrically coupled to the respective N-type doped region 125 and P-type doped region 127.

The avalanche photodiode 300 also includes first and second field plates 311 and 312 within the dielectric layer 150 and on surface 103. The first field plate 311 is electrically coupled to cathode 151 and, accordingly, to the N-type doped region 125. The second field plate 312 is electrically coupled to the anode 152 and to P-type doped region 127. The first field plate 311 extends over a first part 331 of the semiconductor substrate 102 between the N-type and P-type doped regions 125 and 127, respectively. The second field plate 312 extends over a second part 332 of the semiconductor substrate 102 between the N-type and P-type doped regions 125 and 127, respectively. The first and second field plates 311 and 312 are separated by a gap 345 having a length D1. At least a portion of the first field plate 311 is between the cathode 151 and the N-type doped region 125. Similarly, at least a portion of the second field plate 312 is between the anode 152 and the P-type doped region 127. The field plates 311 and 312 are electrically conductive field plates. In one example, the first and second field plates 311 and 312 include polycrystalline silicon (poly silicon). In another example, the first and second field plates 311 and 312 include a metal (e.g., aluminum, copper, etc.).

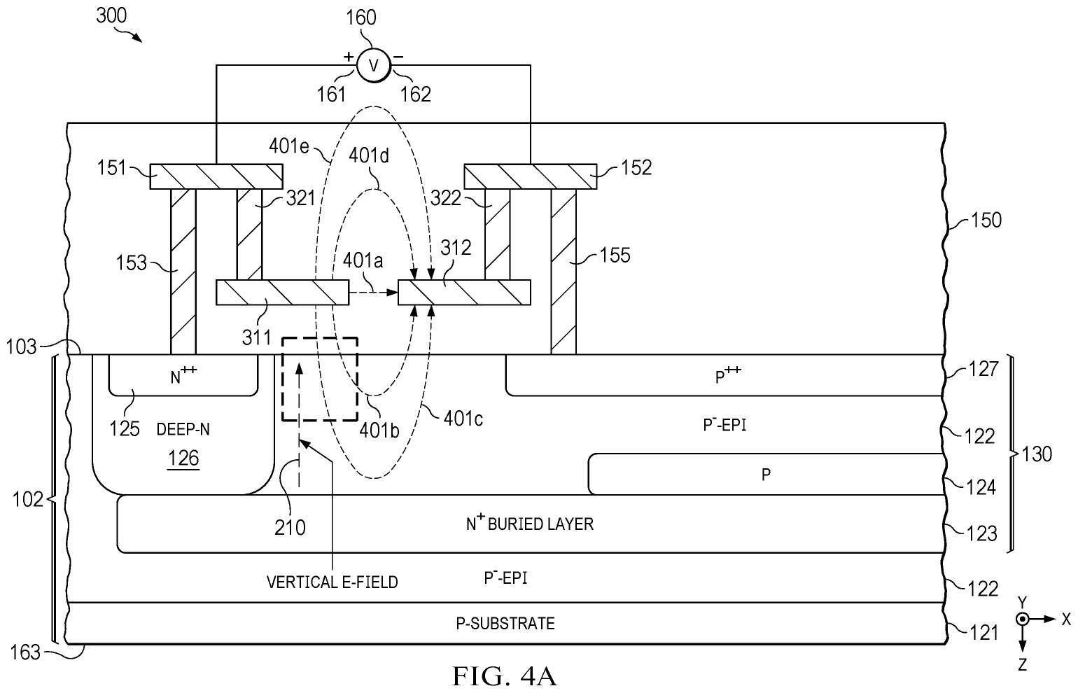

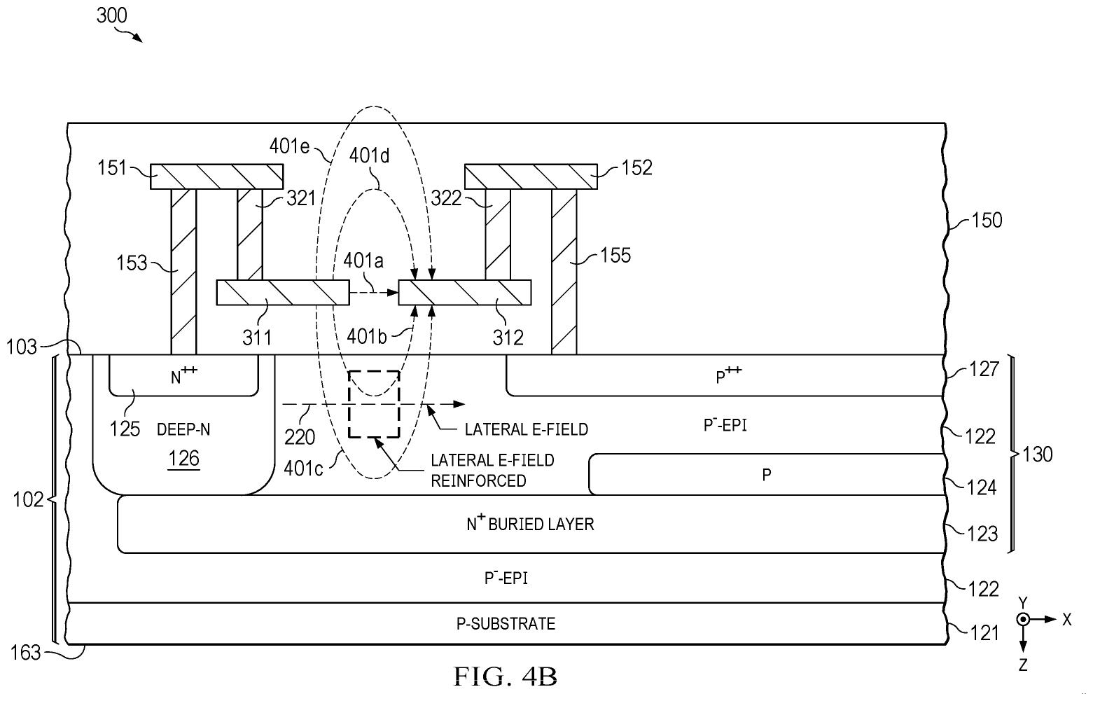

Referring to FIG. 4A, which is the same cross-sectional view of avalanche photodiode 300 as in FIG. 3, because the first and second field plates 311 and 312 are electrically coupled to the respective cathode 151 and anode 152, the same bias voltage from bias voltage circuit 160 is applied across field plates 311 and 312. As a result of the voltage applied across field plates 311 and 312, an electric field is created between the field plates. The electric field is represented by electric field lines 401a, 401b, 401c, 401d, and 401e. Electric field line 401a is between the field plates, and electric field lines 401b-401e are curved fringing field lines. Fringing field lines 401b and 401c closer to the first field plate 311 than the second field plate 312 have a direction that is generally opposite that of the vertical field 210 described above. Accordingly, to a large extent the fringing electric field created between the first and second field plates 311 and 312 greatly reduces the vertical electric field 210, and/or move the high equipotential lines of the vertical electric field 210 away from dielectric layer/semiconductor substrate interface into the vertical PN junction. Because the vertical electric field 210 is substantially smaller for avalanche photodiode 300 than for avalanche photodiode 100, the aforementioned hot carrier effect can be reduced, and advantageously fewer or no electrons penetrate into the dielectric layer 150.

FIG. 4B is the same cross-sectional view of avalanche photodiode 300 as in FIG. 4A. The curved fringing field lines 401b and 401c approximately half-way between the field plates 311 and 312 are in the same direction as lateral electric field 220, described above. Accordingly, the strength of the electric field in the horizontal/lateral direction is increased due to the additive nature of fringing field lines 401b/401c and electric field 220. The strength of the field plate electric field between the field plates 311 and 312 can be set by a gap distance between the field plates 311 and 322. The gap distance can be configured such that the vertical component of the field plate electric field is large enough to reduce the accumulated charge in the part of dielectric layer 150, which can reduce the accumulated charge in the dielectric layer 150 and increase the breakdown voltage (and critical electric field for breakdown) of the PN junction 131, while the lateral component of the field plate electric field is small enough so as not to exceed the critical electric field. Moreover, although the electric field across the gap between field plates 311 and 312 may be large, the large electric field does not create additional charge carrier in the dielectric layer because of the large band gap of the dielectric layer.

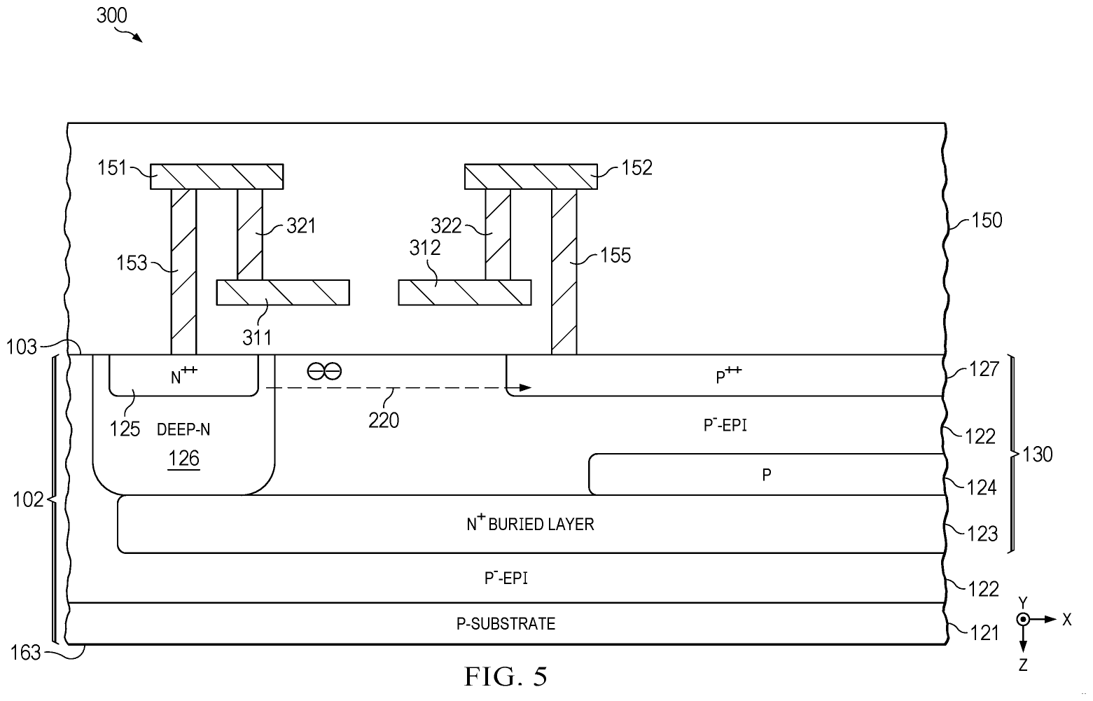

FIG. 5 is the same cross-sectional view of avalanche photodiode 300 as in FIGS. 4A and 4B. FIG. 5 illustrates that the strengthened lateral electric field 220 due to the fringing field lines created by the voltage applied to the first and second field plates 311 and 312. Despite the increased lateral electric field 220, because the reduction of the vertical electric field 210 in the region between the N-type doped region 125 and the P-type doped region 127, there is less charge accumulated in the dielectric layer above the region, and the critical field for avalanche multiplication in the PN junction 131 is still higher than the strengthened lateral electric field 220. Accordingly, avalanche multiplication in the PN junction 131 can be prevented.

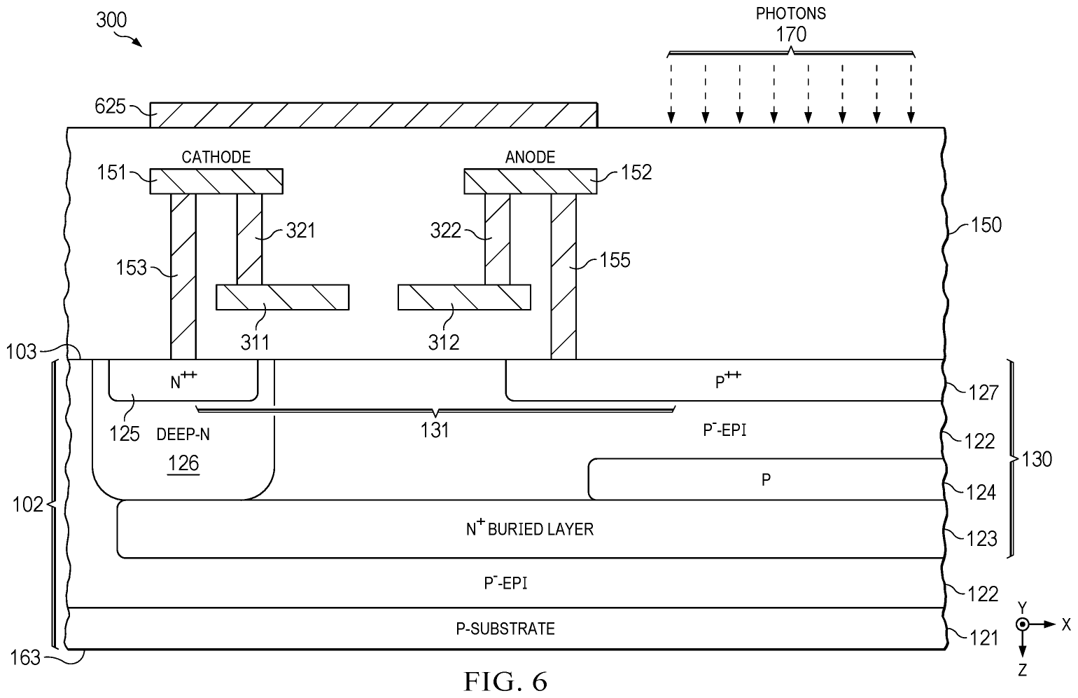

FIG. 6 is a cross-sectional view of avalanche photodiode 300 identical as shown in FIGS. 3-5B. In the example of FIG. 6, the avalanche photodiode 300 includes an optically-opaque layer 625 over a portion of the dielectric layer 150 containing the first and second field plates 311 and 312. In one example, the optically-opaque layer 625 includes a metal (e.g., aluminum, copper, etc.). The optically-opaque layer prevent photons 170 from entering that portion of the dielectric layer 150 in which the cathode 151, anode 152, and first and second field plates 311 and 312 are located.

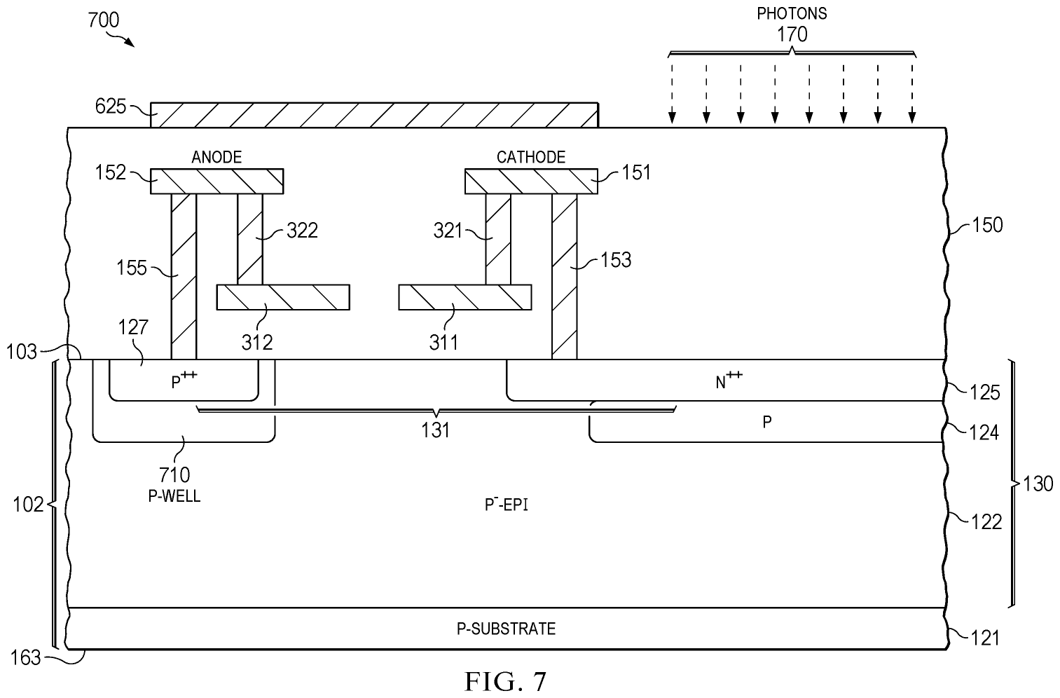

FIG. 7 is a cross-sectional view of an avalanche photodiode 700 in which the position of the cathode 151 and anode 152 is reversed from the example avalanche photodiodes of FIGS. 1-6. In this example, the cathode 151 is over the vertical PN junction 130. The cathode 151 is coupled to the n-doped region 125. The vertical PN junction 130 includes the n-doped region 125 and the P-type doped region 124 and the P-type epi layer 122. The anode 152 is coupled to the P-type doped region 127 which is within a P-type doped well 710. The P-type doped well 710 is within the P-type epi layer 122. As described above, the first and second field plates 311 and 312 are electrically coupled to the respective cathode 151 and anode 152.

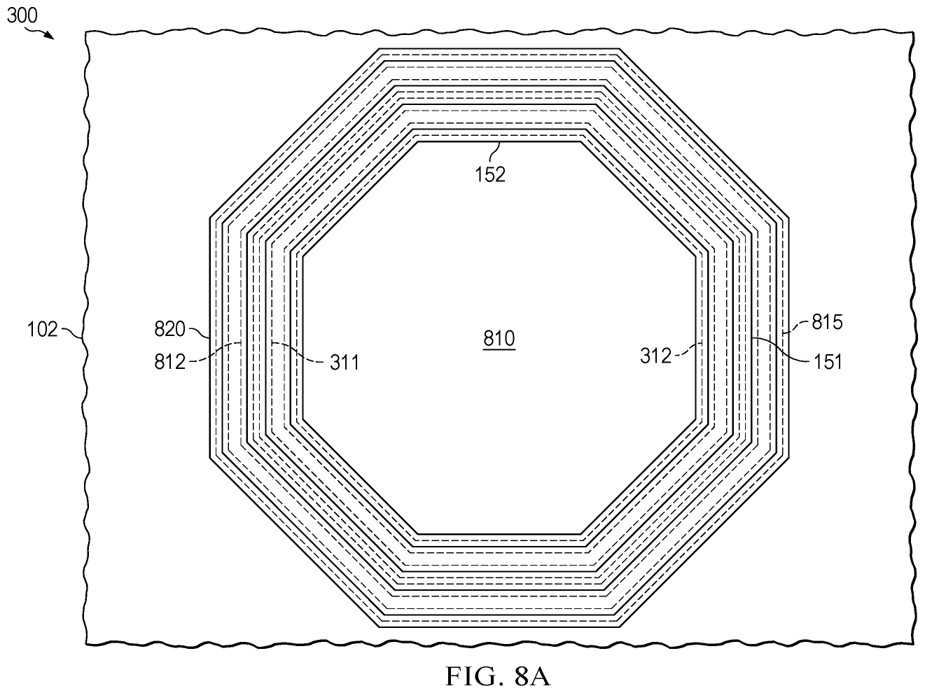

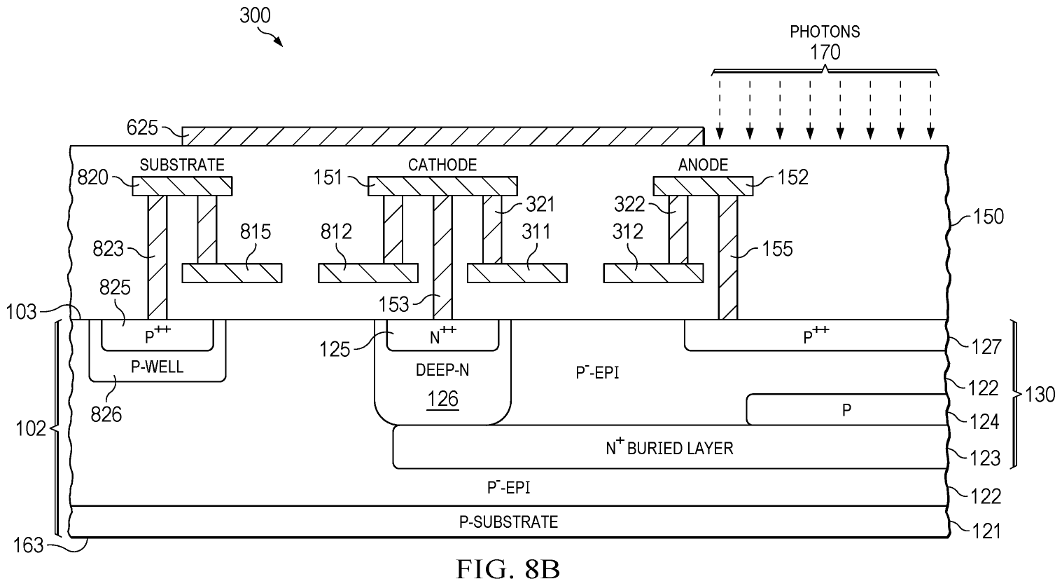

FIG. 8A and FIG. 8B are schematics illustrating an example of avalanche photodiode 300 having ringed structures. FIG. 8A is a top-down view illustrating that, for the example avalanche photodiodes of FIGS. 1-7, the cathode 151, anode 152, first and second field plates 311 and 312, N-type doped region 125, and P-type doped region 127 are ringed structures. The anode 152 is interior of the cathode 151 in this example, which corresponds to the avalanche photodiode of FIGS. 1-6. In another example, the cathode 151 can be interior of the anode 152 such as is shown in the example of FIG. 7. The first and second field plates 311 and 312 are shown in dashed outline because the field plates are below the respective cathode 151 and anode 152.

The example avalanche photodiode of FIG. 8A also includes a terminal 820 electrically coupled to the substrate 102, e.g., to the P-type epi layer 122 and P-type substrate 121. Terminal 820 can be coupled to a voltage source to provide a substrate bias voltage to P-type epi layer 122 and P-type substrate 121. Referring to FIG. 8B, substrate 102 can include a P-type doped region 825 (e.g., a P++ region) an a P-type doped region 826 (e.g., a P-well), where the P-type doped region 825 is formed in and has a higher dopant concentration than P-typed doped region 826. P-typed doped region 825 is coupled to terminal 820 by a conductor 823 (e.g., a metal via). Under normal operation, the substrate bias voltage (e.g., at 0V) is much lower than the voltage at cathode 151, so that a cathode-to-substrate diode between the P-type doped region 825 and the N-type doped region 125 is reverse biased. Terminal 820, cathode 151, and anode 152, as well as underlying portions of substrate 102 underneath can be covered by optically-opaque layer 625, which is shown in FIG. 8B and omitted in FIG. 8A.

Also, the avalanche photodiode includes another pair of field plates 812 and 815. Field plate 812 is coupled to the cathode 151, and field plate 815 is coupled to the substrate terminal 820. Field plate 812 is electrically coupled to the cathode 151, and field plate 815 is electrically coupled to the substrate terminal 820. Field plates 812 and 815 are below the respective cathode 151 and substrate terminal 820 and, accordingly, are shown in dashed outline.

Field plates 812 and 815 can prevent avalanche multiplication in the cathode-to-substrate diode. Specifically, as described above, the cathode can be biased a positive voltage, and both the anode and the substrate can be biased at or close to 0V. Hence, there is also a strongly reverse biased cathode-to-substrate diode. The breakdown voltage of such a diode should be larger than the bias voltage of the cathode-to-anode junction of the avalanche photodiode under normal operation and also does not shift during the lifetime of the photodiode, to prevent avalanche multiplication in the cathode-to-substrate diode. Field plates 812 and 815 can prevent high-energy carriers being injected into the dielectric layer over the substrate-cathode-junction and reduce accumulation of charge in the dielectric field, which can maintain/increase the breakdown voltage of the cathode-to-substrate diode similar to as described above in FIG. 4A

In the example of FIG. 8A, the ringed structures are octagonal but can be other than octagonal in other examples. For example, the ringed structures may be hexagonal, circular, etc. The ringed structures surround a central light transparent region 810 corresponding to the portion 180 of the dielectric layer 150 which receives the photons 170 of light.

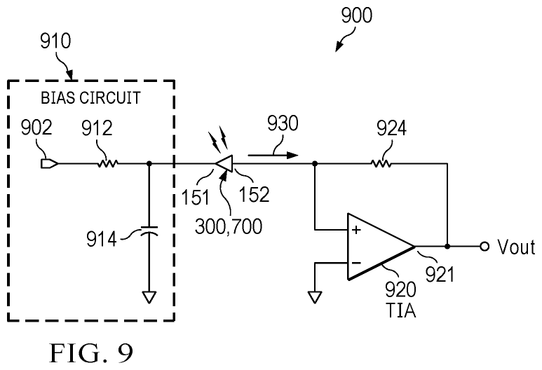

FIG. 9 is a schematic diagram of a circuit 900 which includes a bias circuit 910, an avalanche photodiode 300 or 700, a transimpedance amplifier (TIA) 920, and a resistor 924. In this example, bias circuit 910 includes a resistor 912 coupled to a capacitor 914. Resistor 912 is coupled between a voltage input terminal 902 and the cathode 151 of the avalanche photodiode 300, 700. Capacitor 914 is coupled between the cathode 151 and ground. The positive input of TIA 920 is coupled to the anode 152 of the avalanche photodiode 300, 700. Resistor 924 is coupled between the positive input of TIA 920 and the output 921 of TIA 920.

The resistor 912 and capacitor 914 of the bias circuit 910 form a low-pass filter to filter out higher frequency (e.g., noise) of a voltage at the voltage input terminal 920. Bias circuit 910 provides the filtered voltage from the voltage input terminal 920 to the cathode 151 of avalanche photodiode 300, 700 The negative terminal of TIA 920 is coupled to ground, and accordingly, the positive terminal of TIA 920 also is at the ground potential. Because the anode 152 of the avalanche photodiode 300, 700 is at the ground potential and the cathode 151 is at the voltage of the voltage input terminal 920, avalanche photodiode 300, 700 is reverse-biased.

Avalanche photodiode 300, 700 produces a current 930 based on the intensity of the light it receives. The TIA 920 converts the current 930 from avalanche photodiode 300, 700 to a voltage (Vout) at the output 921. The voltage Vout is given as: Vout=−(R924*I930), where R924 is the resistance of resistor 924 and I930 is the magnitude of current 930.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible, within the scope of the claims.

What is claimed is:

1. A semiconductor device comprising:
a semiconductor substrate having a surface;
an N-type doped region in the semiconductor substrate;
a P-type doped region in the semiconductor substrate, the P-type doped region and the N-type doped region forms a first PN junction oriented along a first axis parallel to the surface;
a second PN junction in the semiconductor substrate, the PN junction including one of the N-type or P-type doped regions and oriented along a second axis that intersects the surface;
a first terminal electrically coupled to the N-type doped region;
a second terminal electrically coupled to the P-type doped region;
a first field plate on the surface, the first field plate electrically coupled to the first terminal and extending over a first part of the semiconductor substrate between the N-type and P-type doped regions; and
a second field plate on the surface, the second field plate electrically coupled to the second terminal and extending over a second part of the semiconductor substrate between the N-type and P-type doped region, the first and second field plates being separated by a gap.

2. The semiconductor device of claim 1, wherein the first field plate is electrically coupled to the first terminal, and the second field plate is electrically coupled to the second terminal.

3. The semiconductor device of claim 1, wherein at least a portion of the first field plate is between the first terminal and the N-type doped region, and at least a portion of the second field plate is between the second terminal and the P-type doped region.

4. The semiconductor device of claim 1, wherein the first and second field plates comprise polycrystalline silicon.

5. The semiconductor device of claim 1, further comprising:
a third terminal electrically coupled to the semiconductor substrate;
a third field plate on the surface and electrically coupled to the third terminal; and
a fourth field plate on the surface and electrically coupled to one of the first terminal or second terminal.

6. The semiconductor device of claim 1, wherein the second PN junction is part of an avalanche photodiode.

7. The semiconductor device of claim 6, wherein the first terminal is a cathode of the avalanche photodiode, and the second terminal is an anode of the avalanche photodiode.

8. The semiconductor device of claim 2, further comprising a dielectric layer over the N-type doped region and the P-type doped region, the first and second field plates in the dielectric layer.

9. The semiconductor device of claim 6, wherein at least a portion of the dielectric layer is transparent.

10. The semiconductor device of claim 9, wherein the P-type doped region is a first P-type doped region, and the semiconductor device further comprises a second P-type doped region under the portion of the dielectric layer that is transparent, the second P-type doped region being part of the PN junction.

11. The semiconductor device of claim 6, further comprising an optically-opaque layer over a portion of the dielectric layer containing the first and second field plates.

12. The semiconductor device of claim 11, wherein the optically-opaque layer comprises a metal.

13. The semiconductor device of claim 1, wherein the N-type doped region and the P-type doped region comprise respective rings in the semiconductor substrate.

14. A circuit comprising:
an avalanche photodiode having a cathode, an anode, a first field plate coupled to the cathode, and a second field plate coupled to the anode; and
a bias circuit coupled to the first and second terminals.

15. The circuit of claim 14, wherein the avalanche photodiode comprises:
a semiconductor substrate having a surface;
an N-type doped region in the semiconductor substrate, the N-type doped region electrically coupled to the cathode;
a P-type doped region in the semiconductor substrate the P-type doped region electrically coupled to the anode, and the P-type doped region and the N-type doped region forming a first PN junction oriented along a first axis parallel to the surface;
a second PN junction in the semiconductor substrate, the second PN junction including one of the N-type or P-type doped regions and oriented along a second axis that intersects the surface.

16. The circuit of claim 15, wherein at least a portion of the first field plate is between the cathode and the N-type doped region, and at least a portion of the second field plate is between the anode and the P-type doped region.

17. The circuit of claim 14, wherein the first and second field plates comprise polycrystalline silicon.

18. An avalanche photodiode comprising:
a semiconductor substrate having a surface;
an N-type doped region in the semiconductor substrate;
a P-type doped region in the semiconductor substrate, the P-type doped region and the N-type doped region forming a first PN junction oriented along a first axis parallel to the surface;
a second PN junction in the semiconductor substrate, the second PN junction including one of the N-type or P-type doped regions and oriented along a second axis that intersects the surface;
a first terminal electrically coupled to the N-type doped region;
a second terminal electrically coupled to the P-type doped region;
a first conductive plate on the surface, the first conductive plate electrically coupled to the N-type doped region and extending over a first part of the semiconductor substrate between the N-type and P-type doped regions;
a second conductive plate on the surface, the second conductive plate electrically coupled to the P-type doped region and extending over a second part of the semiconductor substrate between the N-type and P-type doped region, the first and second field plates being separated by a gap; and
a dielectric layer over the N-type doped region and the P-type doped region, the first and second conductive plates in the dielectric layer.

19. The avalanche photodiode of claim 18, wherein the P-type doped region is a first P-type doped region, and the avalanche photodiode further comprises a second P-type doped region under the portion of the dielectric layer, the second P-type doped region being part of the second PN junction.

20. The avalanche photodiode of claim 18, wherein at least a portion of the first conductive plate is between the cathode and the N-type doped region, and at least a portion of the second conductive plate is between the anode and the P-type doped region.
